(19) United States
(12) Patent Application Publication
(10) Pub. No.: US 2026/0015998 A1
(43) Pub. Date: Jan. 15, 2026

(54) HERMETIC RECIPROCATING COMPRESSOR

(71) Applicant: SAMSUNG ELECTRONICS CO., LTD., Suwon-si (KR)

(72) Inventors: Jonggun KIM, Suwon-si (KR); Incheol HWANG, Suwon-si (KR); Jungwoo PARK, Suwon-si (KR); Kihwan KIM, Suwon-si (KR); Kisun NAM, Suwon-si (KR)

(73) Assignee: SAMSUNG ELECTRONICS CO., LTD., Suwon-si (KR)

(21) Appl. No.: 19/335,793

(22) Filed: Sep. 22, 2025

Related U.S. Application Data
(63) Continuation of application No. PCT/KR2024/003797, filed on Mar. 26, 2024.

(30) Foreign Application Priority Data
Apr. 20, 2023 (KR) 10-2023-0052308
Jul. 3, 2023 (KR) 10-2023-0086052

(51) Int. Cl. F04B 17/03

(52) U.S. Cl. CPC F04B 17/03; F04B 2201/08; F04B 2203/0209

(57) ABSTRACT

A reciprocating compressor including a cylinder; a piston disposed to reciprocate a certain distance inside the cylinder; a connecting rod connected to the piston; a rotation shaft configured to operate the connecting rod; a rotor configured to rotate integrally with the rotation shaft; and a stator disposed inside of the rotor along a direction toward the rotation shaft or outside the rotor along the direction toward the rotation shaft. A speed fluctuation rate of the rotor is 20% or less is achieved based on consideration of a relationship between a moment of inertia of the rotor, an internal pressure of the cylinder, a cross-sectional area and a stroke length of the piston, and a minimum speed of the rotor.

### CROSS-REFERENCE TO RELATED APPLICATION

This application is a continuation application is a continuation application, under 35 U.S.C. § 111(a), of international application No. PCT/KR2024/003797, filed Mar. 26, 2024, which claims priority under 35 U. S. C. § 119 to Korean Patent Application No. 10-2023-0052308, filed Apr. 20, 2023, and Korean Patent Application No. 10-2023-0086052, filed Jul. 3, 2023, the disclosures of which are incorporated herein by reference in their entireties.

### TECHNICAL FIELD

The disclosure relates to a hermetic reciprocating compressor, and more particularly, to a hermetic reciprocating compressor equipped with a rotor having an optimal moment of inertia.

### BACKGROUND ART

A compressor is a mechanical device that compresses an introduced gas to increase its pressure and discharges the compressed gas. Compressors may be divided into reciprocating type compressors and rotating type compressors according to their operating principles.

The rotating type compressors include rotary compressors and scroll compressors.

The reciprocating type compressors include a reciprocating compressor that converts the rotational motion of a motor into the linear reciprocating motion of a piston using a crank shaft and a connecting rod to suck in, compress, and discharge gas.

In general, the reciprocating compressor uses an inner rotor type motor to generate a rotational power.

However, because the inner rotor type motor has a rotor positioned on the inside of a stator, the moment of inertia of the rotor may be limited by the size of the stator.

In order to increase the moment of inertia of the rotor, an outer rotor type motor may be used in which the rotor is positioned on the outside of the stator.

### DISCLOSURE OF INVENTION

### Technical Solution

A reciprocating compressor according to one or more embodiments of the disclosure may include: a cylinder; a piston to be disposed to reciprocate a certain distance inside the cylinder; a connecting rod to be connected to the piston; a rotation shaft configured to operate the connecting rod; a rotor configured to rotate integrally with the rotation shaft; and a stator to be disposed on an inside of the rotor along a direction toward the rotation shaft or an outside of the rotor along the direction toward the rotation shaft. According to one or more embodiments of the disclosure a speed fluctuation rate of the rotor is 20% or less, a moment of inertia of the rotor, an internal pressure of the cylinder, a cross-sectional area and a stroke length of the piston, and a minimum speed of the rotor may have a relationship as follows:

$$moment of inertia of rotor \geq \frac{\begin{matrix}internal pressure of cylinder \times cross - \\ sectional area of pistion \times stroke length of pistion\end{matrix}}{minimum {speed}^{2}} \times α$$

Here, a unit of the moment of inertia of the rotor may be kgcm2, a unit of the internal pressure of the cylinder may be kgf/cm2, a unit of cross-sectional area of the piston may be cm2, a unit of the stroke length of the piston may be cm, a unit of the minimum speed may be round/second (rps), and a may be a coefficient of the moment of inertia of the reciprocating compressor.

According to one or more embodiments of the disclosure, based on the rotor being disposed on an inside of the stator, the moment of inertia of the rotor may be 4.7 to 8.9 kgcm2.

According to one or more embodiments of the disclosure, based on the rotor being disposed on an outside of the stator, the moment of inertia of the rotor may be 8.3 to 15.6 kgcm2.

According to one or more embodiments of the disclosure, based on the rotor being disposed on an inside of the stator, the minimum speed of the rotor may be 11.7 rps.

According to one or more embodiments of the disclosure, based on the rotor being disposed on an outside of the stator, the minimum speed of the rotor may be 8.3 rps.

According to one or more embodiments of the disclosure, based on the rotor being disposed on an inside of the stator, the coefficient of the moment of inertia may be 20.

According to one or more embodiments of the disclosure, based on the rotor being disposed on an outside of the stator, the coefficient of the moment of inertia may be 18.

According to one or more embodiments of the disclosure, the speed fluctuation rate of the rotor may have a relationship as follows:

$$speed fluctuation rate = \frac{instaneous maximum speed - instaneous minimum speed}{command speed} \times 100 \%$$

According to one or more embodiments of the disclosure, the internal pressure of the cylinder may be 7.863 kgf/cm2.

According to one or more embodiments of the disclosure, the cylinder, the piston, and the connecting rod may be provided on the upper side of the bearing block, and the stator and the rotor may be provided on the lower side of the bearing block.

### BRIEF DESCRIPTION OF DRAWINGS

These and/or other aspects, features, and advantages of certain embodiments of the disclosure will be more apparent from the following description taken in conjunction with the accompanying drawings, in which:

FIG. 1 is a graph comparing a fixed temperature performance of a constant speed reciprocating compressor and a fixed temperature performance of an inverter reciprocating compressor according to one or more embodiments of the disclosure.

FIG. 2 is a table showing a speed fluctuation rate according to an operating speed of a reciprocating compressor using an inner rotor type motor according to the prior art.

FIG. 3A is a graph illustrating a speed fluctuation rate when a reciprocating compressor using an inner rotor type motor according to the prior art operates at a minimum speed.

FIG. 3B is a graph illustrating a speed fluctuation rate when a reciprocating compressor using an inner rotor type motor according to the prior art operates at a main operating speed.

FIG. 3C is a graph illustrating a speed fluctuation rate when a reciprocating compressor using an inner rotor type motor according to the prior art operates at a maximum speed.

FIG. 4 is a table showing a speed fluctuation rate at a minimum speed according to the displacement of a reciprocating compressor using an inner rotor type motor according to the prior art.

FIG. 5 is a block diagram illustrating a control flow of a reciprocating compressor used in a home appliance according to one or more embodiments of the disclosure.

FIG. 6 is a view conceptually illustrating a relationship between a rotor, a connecting rod, a piston, and a cylinder of a reciprocating compressor according to one or more embodiments of the disclosure.

FIG. 7 is a graph illustrating a change in an internal pressure of a cylinder while a rotor makes one rotation according to one or more embodiments of the disclosure.

FIG. 8 is a table showing a target minimum speed, a target speed fluctuation rate, a moment of inertia, and a coefficient according to displacement of a reciprocating compressor using an outer rotor type motor according to one or more embodiments of the disclosure.

FIG. 9 is a table showing a target minimum speed, a target speed fluctuation rate, a moment of inertia, and a coefficient according to displacement of a reciprocating compressor using an inner rotor type motor according to one or more embodiments of the disclosure.

FIG. 10 is a cross-sectional view illustrating a reciprocating compressor according to one or more embodiments of the disclosure.

FIG. 11 is a table showing a speed fluctuation rate according to an operating speed of a reciprocating compressor using an outer rotor type motor according to one or more embodiments of the disclosure.

FIG. 12A is a graph illustrating a speed fluctuation rate when a reciprocating compressor using an outer rotor type motor according to one or more embodiments of the disclosure operates at a low speed.

FIG. 12B is a graph illustrating a speed fluctuation rate when a reciprocating compressor using an outer rotor type motor according to one or more embodiments of the disclosure operates at a main operating speed.

FIG. 12C is a graph illustrating a speed fluctuation rate when a reciprocating compressor using an outer rotor type motor according to one or more embodiments of the disclosure operates at a maximum speed.

FIG. 13 is a cross-sectional view illustrating a reciprocating compressor according to one or more embodiments of the disclosure.

### BEST MODE FOR CARRYING OUT THE INVENTION

Various embodiments of this document and terms used herein are not intended to limit the technical features described in this document to specific embodiments, but should be understood to include various modifications, equivalents, or alternatives of the embodiments.

In connection with the description of the drawings, similar reference numbers may be used for similar or related components.

The singular form of a noun corresponding to an item may include one or more of the above item, unless the relevant context clearly indicates otherwise.

In this document, each of phrases such as “A or B,” “at least one of A and B,” “at least one of A or B,” “A, B, or C,” “at least one of A, B, and C,” “at least one of A, B, C” may include any one of the items listed together with the corresponding phrase, or any possible combination thereof.

The term “and/or” includes any element of a plurality of related described elements or a combination of a plurality of related described elements.

Terms such as “first,” “second,” “primary,” or “secondary” may be used simply to distinguish one component from other components, and do not limit the corresponding components in other respects (e.g., importance or order).

When a component (e.g., a first component) is said to be “coupled” or “connected” to another component (e.g., a second component), with or without the terms “functionally” or “communicatively,” it means that the component can be connected to the other component directly (e.g., wired), wirelessly, or through a third component.

Terms such as “include” or “have” are intended to designate the presence of features, numbers, steps, operations, components, parts, or combinations thereof described in the embodiment, but do not preclude the presence or addition of one or more other features, numbers, steps, operations, components, parts, or combination thereof.

When a component is said to be “connected,” “coupled,” “supported,” or “in contact” with another component, this means not only cases where the components are directly connected, coupled, supported, or contacted, but also cases where the components are indirectly connected, coupled, supported, or contacted through a third component.

When a component is said to be located “on” other component, this includes not only cases where the component is in contact with the other component, but also cases where another component exits between the two components.

Further, terms such as ‘leading end’, ‘rear end’, ‘upper side’, ‘lower side’, ‘top end’, ‘bottom end’, etc. used in the disclosure are defined with reference to the drawings. However, the shape and position of each component are not limited by these terms.

This disclosure relates to a hermetic reciprocating compressor 1 having an optimal moment of inertia to reduce a minimum speed and a speed fluctuation rate at the minimum speed compared to a reciprocating compressor according to the prior art.

Recent refrigerators are required to have a high fixed temperature performance. The fixed temperature performance refers to the performance that can preserve the taste, flavor, and texture of food stored in a refrigerator by minimizing temperature changes with respect to a target temperature.

In order to increase the fixed temperature performance of the refrigerator, it may be required to lower a minimum speed of a compressor used in a refrigeration cycle of the refrigerator as much as possible and minimize a speed fluctuation rate at the minimum speed.

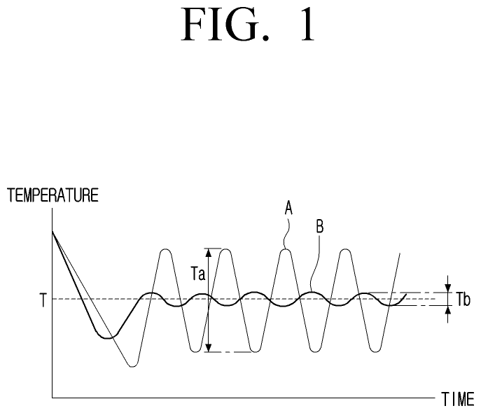

FIG. 1 is a graph comparing a fixed temperature performance of a constant-speed reciprocating compressor and a fixed temperature performance of an inverter reciprocating compressor. In FIG. 1, A is a curve showing the operation of a constant speed compressor to maintain a target temperature, and B is a curve showing the operation of an inverter compressor to maintain a target temperature.

Here, the constant speed compressor refers to a reciprocating compressor whose motor speed cannot be changed and whose motor can only be operated at a fixed speed. Therefore, in the constant-speed compressor, the compressor is turned off when the temperature reaches a target temperature, and turned on when the temperature rises above the target temperature. The inverter compressor refers to a reciprocating compressor that can change a motor speed using an inverter.

Referring to FIG. 1, a constant-speed reciprocating compressor is repeatedly turned on and off to maintain a target temperature T, so a temperature change Ta is large. However, an inverter reciprocating compressor has a small temperature change Tb to maintain the target temperature.

This disclosure relates to a reciprocating compressor capable of controlling a speed of a motor using an inverter. In order to improve a fixed-temperature performance of a refrigerator including a reciprocating compressor using an inverter, it may be required to continuously operate the motor of the reciprocating compressor at as low a speed as possible, with minimal speed fluctuation, and without turning it on and off while minimizing the temperature change for the target temperature. For example, it may be required that the motor of the reciprocating compressor rotates at a rotation speed of less than 1,000 rpm and the speed fluctuation rate at the minimum speed is 20% or less.

However, the reciprocating compressor according to the prior art has a problem that the minimum speed is large and the speed fluctuation rate at the minimum speed is large.

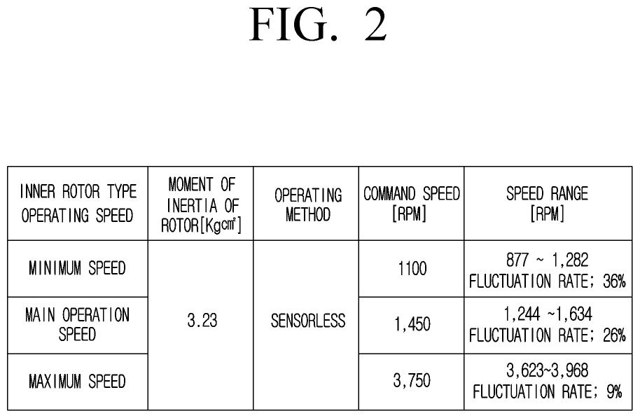

FIG. 2 is a table showing a speed fluctuation rate according to an operation speed of a reciprocating compressor using an inner rotor type motor according to the prior art.

At this time, the moment of inertia of the rotor of the reciprocating compressor is 2.23 Kgcm2, and the operating method is a sensorless method.

Referring to FIG. 2, when the reciprocating compressor rotates at the minimum speed of the commanded speed of 1,100 rpm, the range of the actual speed of the rotor is 877 rpm to 1,282 rpm, so the speed fluctuation rate is about 36%.

When the reciprocating compressor rotates at the main operation speed of the commanded speed of 1,450 rpm, the actual speed range of the rotor is 1,244 rpm to 1,634 rpm, so the speed fluctuation rate is about 26%.

When the reciprocating compressor rotates at the maximum speed of the commanded speed of 3,750 rpm, the actual speed range of the rotor is 3,623 rpm to 3,968 rpm, so the speed fluctuation rate is about 9%.

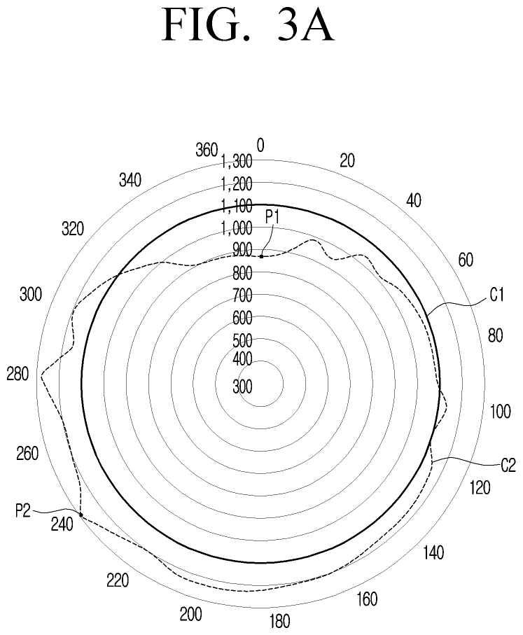

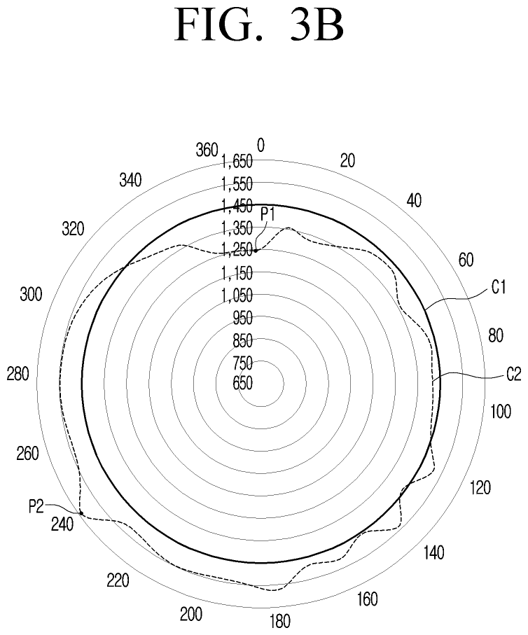

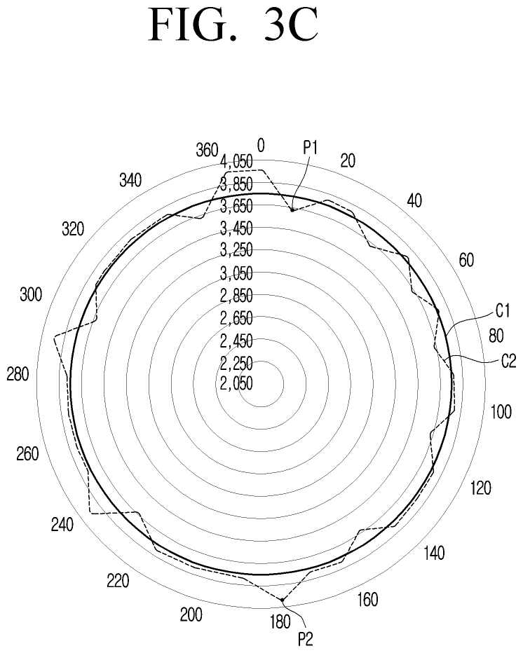

These command speeds and the actual speeds of the rotor are shown in FIGS. 3A, 3B, and 3C.

FIG. 3A is a graph illustrating a speed fluctuation rate when a reciprocating compressor using an inner rotor type motor according to the prior art operates at a minimum speed. FIG. 3B is a graph illustrating a speed fluctuation rate when a reciprocating compressor using an inner rotor type motor according to the prior art operates at a main operation speed. FIG. 3C is a graph illustrating a speed fluctuation rate when a reciprocating compressor using an inner rotor type motor according to the prior art operates at a maximum speed.

In FIGS. 3A, 3B, and 3C, multiple concentric circles represent a rotation speed of the rotor, and the unit is rpm. The numbers on the outermost circle represent the rotational angle of the rotor, and the unit is degree. In addition, in FIGS. 3A, 3B, and 3C, the solid line represents the command speed, and the dotted line represents the actual speed of the rotor. The actual speed of the rotor is the instantaneous speed of the rotor measured using an ultra-high-speed camera.

Referring to FIG. 3A, the command speed, which is the minimum speed, is constant at 1,100 rpm while the rotor rotates once, that is, from 0 degrees to 360 degrees. However, the actual speed of the rotor varies from a maximum of 1,282 rpm to a minimum of 877 rpm. In detail, the instantaneous minimum speed is 877 rpm at about zero (0) degrees P1, and the instantaneous maximum speed is 1,282 rpm at about 240 degrees P2.

The speed fluctuation rate may be defined as a ratio of the difference between the instantaneous maximum speed and the instantaneous minimum speed with respect to the command speed. In other words, the speed fluctuation rate may be expressed by the following equation (1).

$$speed fluctuation rate = \frac{instaneous maximum speed - instaneous minimum speed}{command speed} \times 100 \% \qquad ( 1 )$$

Therefore, in the case that the command speed is 1,100 rpm, the instantaneous maximum speed is 1,282 rpm, and the instantaneous minimum speed is 877 rpm, the speed fluctuation rate is 36.8% when calculated using the equation (1). Accordingly, when the command speed is 1,100 rpm, the speed fluctuation rate of the rotor may be said to be approximately 36%.

Referring to FIG. 3B, the command speed, which is the main operation speed, is constant at 1,450 rpm while the rotor rotates once, that is, from 0 degrees to 360 degrees. However, the actual speed of the rotor varies from a maximum of 1,634 rpm to a minimum of 1,244 rpm. In detail, the instantaneous minimum speed is 1,244 rpm at about zero (0) degrees P1, and the instantaneous maximum speed is 1,634 rpm at about 240 degrees P2.

Therefore, in the case that the command speed is 1,450 rpm, the instantaneous maximum speed is 1,634 rpm, and the instantaneous minimum speed is 1,244 rpm, the speed fluctuation rate is 26.9% when calculated using the equation (1). Accordingly, when the command speed is 1,450 rpm, the speed fluctuation rate of the rotor may be said to be approximately 26%.

Referring to FIG. 3C, the command speed, which is the maximum speed, is constant at 3,750 rpm while the rotor rotates once, that is, from 0 degrees to 360 degrees. However, the actual speed of the rotor varies from a maximum of 3,968 rpm to a minimum of 3,623 rpm. In detail, the instantaneous minimum speed is 3,623 rpm at about 10 degrees P1, and the instantaneous maximum speed is 3,968 rpm at about 240 degrees P2.

Therefore, in the case that the command speed is 3,750 rpm, the instantaneous maximum speed is 3,968 rpm, and the instantaneous minimum speed is 3,623 rpm, the speed fluctuation rate is 9.2% when calculated using the equation (1). Accordingly, when the command speed is 3,750 rpm, the speed fluctuation rate of the rotor may be said to be approximately 9%.

The above description is about the speed fluctuation rate of a reciprocating compressor with a displacement of 15.3 cc.

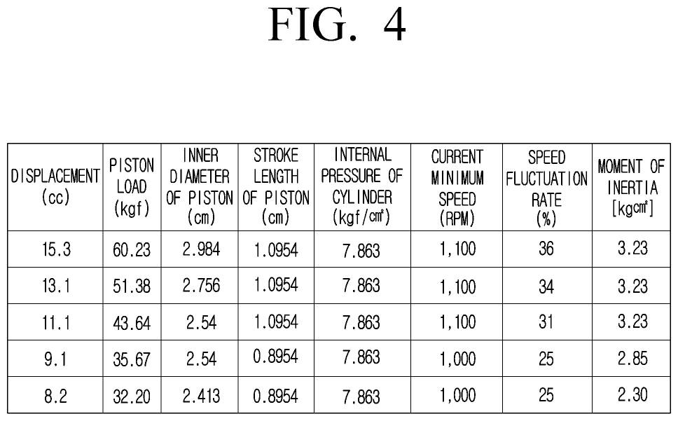

The speed fluctuation rate of the reciprocating compressor as described above may vary depending on the displacement of the reciprocating compressor. The speed fluctuation rate of the reciprocating compressor depending on the displacement is shown in FIG. 4

FIG. 4 is a table showing a speed fluctuation rate at a minimum speed depending on a displacement of a reciprocating compressor using an inner rotor type motor according to the prior art.

In the case of a reciprocating compressor with a displacement of 15.3 cc, the speed fluctuation rate is 36% when operating at a minimum speed of 1,100 rpm.

In the case of a reciprocating compressor with a displacement of 13.1 cc, the speed fluctuation rate is 34% when operating at a minimum speed of 1,100 rpm.

In the case of a reciprocating compressor with a displacement of 11.1 cc, the speed fluctuation rate is 31% when operating at a minimum speed of 1,100 rpm.

In the case of a reciprocating compressor with a displacement of 9.1 cc, the speed fluctuation rate is 25% when operating at a minimum speed of 1,000 rpm.

In the case of a reciprocating compressor with a displacement of 8.2 cc, the speed fluctuation rate is 25% when operating at a minimum speed of 1,000 rpm.

As can be seen in FIG. 4, the reciprocating compressor using an inner rotor type motor according to the prior art has the speed fluctuation rate of 25% or more when operating at a minimum speed regardless of the displacement.

Because the inside of the reciprocating compressor with a motor installed is a high-temperature and high-pressure environment, a sensor capable of detecting a position of the rotor may not be disposed inside the reciprocating compressor. Therefore, in general, the reciprocating compressor may use a sensorless control method in which no sensor is disposed inside the reciprocating compressor to control the speed of the motor with an inverter.

For example, the position of the rotor may be estimated using an algorithm that uses a zero cross point ZCP of a back electromotive force (hereinafter referred to as a ZCP algorithm) as the sensorless control method. However, because the reciprocating compressor is subject to an eccentric load, a back electromotive force error may occur when operating at low speeds. Accordingly, when the ZCP algorithm is used, an error may also occur in identifying the position of the rotor. As a result, torque pulsation may occur at low speeds, causing speed fluctuations of the rotor.

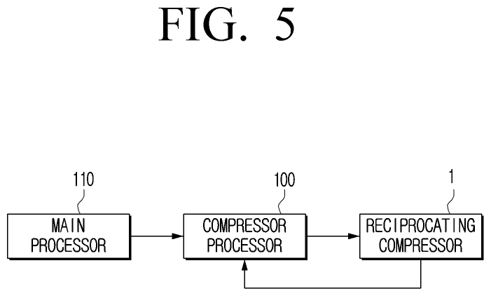

FIG. 5 is a block diagram illustrating a control flow of a reciprocating compressor used in a home appliance.

Referring to FIG. 5, a main processor 110 of a home appliance including a reciprocating compressor 1, for example, a refrigerator, may command a speed to a compressor processor 100. Then, the compressor processor 100 may control the speed of the reciprocating compressor 1 according to the command speed of the main processor 110. The compressor processor 100 may include an inverter. Therefore, the compressor processor 100 may arbitrarily control the speed of the reciprocating compressor 1 according to the command speed of the main processor 110.

The compressor processor 100 may be configured to detect the back electromotive force and current of the reciprocating compressor 1 and identify the position of the rotor using the ZCP algorithm.

However, when the compressor processor 100 operates the reciprocating compressor 1 at a low speed, an error may occur in the back electromotive force, so the position of the rotor recognized by the compressor processor 100 may be different from the actual position of the rotor. When the position of the rotor recognized by the compressor processor 100 is different from the actual position of the rotor, torque pulsation may occur, causing the speed of the rotor to fluctuate.

However, in order to improve the fixed-temperature performance of the refrigerator, it may be necessary to lower the minimum speed of the reciprocating compressor than the minimum speed of the reciprocating compressor according to the prior art, and also to lower the speed fluctuation rate at the minimum speed.

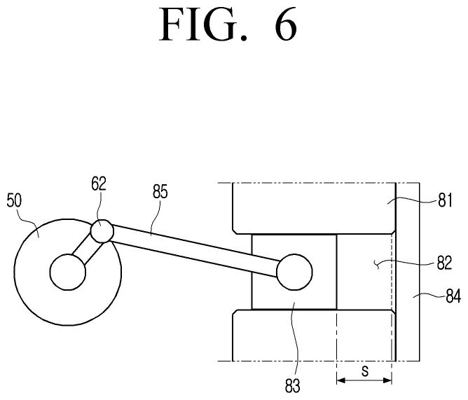

FIG. 6 is a view conceptually illustrating a relationship between a rotor 50, a connecting rod 85, a piston 83, and a cylinder 81 of a reciprocating compressor 1 according to one or more embodiments of the disclosure.

Referring to FIG. 6, a compression part of the reciprocating compressor 1 may include a cylinder 81 and a piston 83. The cylinder 81 may include a through hole formed with a circular cross-section. The piston 83 may be disposed inside the through hole so as to be able to slide. The piston 83 may be connected to one end of the connecting rod 85. The other end of the connecting rod 85 may be connected to the crank shaft 62. The crank shaft 62 may be configured to rotate by the rotor 50. The crank shaft 62 may be eccentric with respect to the rotation axis of the rotor 50. Therefore, when the rotor 50 rotates, the piston 83 may perform a linear reciprocating motion by a certain distance S inside the cylinder 81.

One end of the through hole of the cylinder 81 may be covered with a cylinder head 84. The cylinder head 84 may be provided with an inlet valve and a discharge valve through which refrigerant is introduced and discharged. The internal space of the through hole between the piston 83 and the cylinder head 84 may form a compression chamber 82.

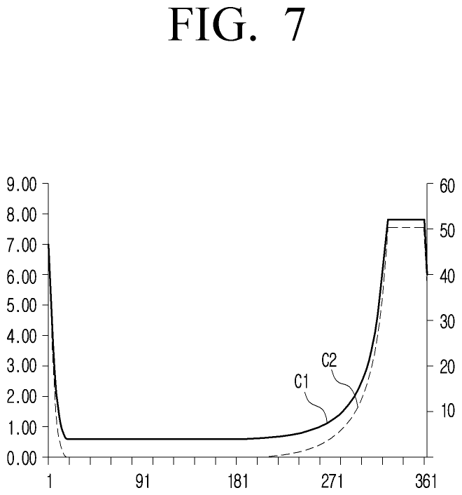

While the rotor 50 rotates once, the pressure of the compression chamber 82, that is, the internal pressure of the cylinder 81, may change. The change in the internal pressure of the cylinder with respect to the rotational angle of the rotor 50 is illustrated in FIG. 7.

FIG. 7 is a graph illustrating a change in pressure inside a cylinder while a rotor makes one rotation. In FIG. 7, the horizontal axis represents the rotational angle of the rotor, and the unit is degree. The left vertical axis represents the internal pressure of the cylinder, and the unit is kgf/cm2. Curve C1 represents the change in the internal pressure of the cylinder according to the rotational angle of the rotor, and curve C2 represents the compression force of the piston according to the rotational angle of the rotor.

Referring to FIG. 7, the internal pressure of the cylinder is maintained at a minimum pressure while the rotor rotates from about 20 degrees to about 220 degrees, increases after passing 220 degrees, and becomes a maximum when the rotor reaches about 320 degrees, maintaining the maximum pressure until 360 degrees. After passing 360 degrees, the internal pressure of the cylinder begins to decrease, and when it reaches about 20 degrees, the internal pressure of the cylinder becomes minimum. At this time, the maximum value of the internal pressure of the cylinder is about 7.863 kgf/cm2, and the minimum value thereof is about 0.6 kgf/cm2.

The compression force of the piston may change while the rotor rotates once. The compression force of the piston may change similarly to the internal pressure of the cylinder while the rotor rotates once. However, the compression force of the piston may be smaller than the internal pressure of the cylinder. For example, the compression force of the piston may be zero (0) while the internal pressure of the cylinder is maintained at the minimum pressure.

Referring to FIG. 6, it can be seen that the kinetic energy of the rotor 50 is related to the compression force of the piston 83, that is, the refrigeration capacity of the reciprocating compressor 1. In other words, the moment of inertia of the rotor 50 and the piston load are related to each other.

Therefore, in this disclosure, in order to lower the minimum speed and the speed fluctuation rate of the reciprocating compressor 1 compared to the minimum speed and the speed fluctuation rate of the reciprocating compressor according to the prior art, the moment of inertia of the rotor 50 and the piston load may be defined by the following equation (2).

$$moment of inertia of rotor \geq \frac{\begin{matrix}internal pressure of cylinder \times cross - \\ sectional area of pistion \times stroke length of pistion\end{matrix}}{minimum {speed}^{2}} \times α \qquad ( 2 )$$

In equation (2), the unit of the moment of inertia of rotor is kgcm2, the unit of the internal pressure of cylinder is kgf/cm2, the unit of the cross-sectional area of piston is cm2, the unit of the stroke length of piston is cm, and the unit of the minimum speed is round/second (rps). The internal pressure of the cylinder refers to the maximum pressure applied to the compression chamber of the cylinder.

α is the coefficient of moment of inertia of the reciprocating compressor. The coefficient of the moment of inertia varies depending on the type of motor used in the reciprocating compressor. For example, in the case of an inner rotor type reciprocating compressor using the inner rotor, the coefficient of moment of inertia is 20. In the case of an outer rotor type reciprocating compressor using the outer rotor, the coefficient of moment of inertia is 18. The coefficient of moment of inertia may be obtained thorough experiments.

Internal pressure of cylinder x cross-sectional area of piston x stroke length of piston means the load of the piston. Here, the cylinder and the piston may form the compression part of the reciprocating compressor. The piston may be inserted into the cylinder, and may be installed to reciprocate in a straight line for a certain distance (stroke length).

In order to prove the above equation (2), because the moment of inertia of the outer rotor of the outer rotor type motor is greater than the moment of inertia of the inner rotor of the inner rotor type motor, separate experiments were conducted on a reciprocating compressor using the outer rotor type motor and a reciprocating compressor using the inner rotor type motor.

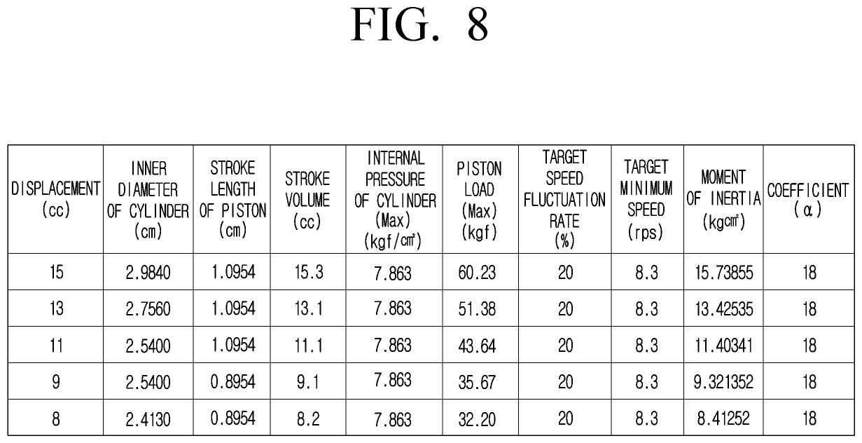

FIG. 8 is a table showing a target minimum speed, a target speed fluctuation rate, moment of inertia, and coefficient according to displacement of a reciprocating compressor using an outer rotor type motor according to one or more embodiments of the disclosure.

In FIG. 8, the target minimum speed represents the rotation speed of the rotor, and the moment of inertia refers to the moment of inertia of the rotor. The displacement is the displacement of the reciprocating compressor, and represents the stroke volume of the cylinder. The target speed fluctuation rate was experimentally confirmed using an ultra-high-speed camera.

In the case of calculating the moment of inertia of the rotor of a reciprocating compressor with a displacement of 15, when the internal pressure of cylinder, the cross-sectional area of piston, the stroke length of piston, the target minimum speed, and the coefficient of the displacement of 15 in FIG. 8 are substituted into the above equation (2), 15.73855 may be obtained as the moment of inertia of the rotor. When the rotor of this reciprocating compressor is measured with an ultra-high-speed camera and the speed fluctuation rate is calculated, the actual speed fluctuation rate may become 20% or less. Therefore, the target speed fluctuation rate of FIG. 8 may be satisfied.

In the case of calculating the moment of inertia of the rotor of a reciprocating compressor with a displacement of 13, when the internal pressure of cylinder, the cross-sectional area of piston, the stroke length of piston, the target minimum speed, and the coefficient of the displacement of 13 in FIG. 8 are substituted into the above equation (2), 13.42535 may be obtained as the moment of inertia of the rotor. When the rotor of this reciprocating compressor is measured with an ultra-high-speed camera and the speed fluctuation rate is calculated, the actual speed fluctuation rate may become 20% or less. Therefore, the target speed fluctuation rate of FIG. 8 may be satisfied.

In the case of a displacement of 11, using the equation (2) in the same way as the displacements of 15 and 13 described above, 11.40341 may be obtained as the moment of inertia of the rotor.

In the case of a displacement of 9, using the equation (2) in the same way as the displacements of 15 and 13 described above, 9.321352 may be obtained as the moment of inertia of the rotor.

In the case of a displacement of 8, using the equation (2) in the same way as the displacements of 15 and 13 described above, 8.41252 may be obtained as the moment of inertia of the rotor.

In the case of displacements of 11, 9, and 8, when the rotor of this reciprocating compressor is measured with an ultra-high-speed camera and the speed fluctuation rate thereof is calculated, the actual speed fluctuation rate may become 20% or less. Therefore, the target speed fluctuation rate of FIG. 8 may be satisfied.

Therefore, from FIG. 8 it can be seen that when the moment of inertia of the rotor is set to 8.3 kgcm2 to 15.6 kgcm2, the minimum speed of the rotor may be set to 8.3 rps, i.e., 500 rpm, and the speed fluctuation rate at the minimum speed may be set to 20% or less.

When the moment of inertia of the rotor is less than 8.3 kgcm2, the speed fluctuation rate at the minimum speed may exceed 20%. In addition, when the moment of inertia of the rotor exceeds 15.6 kgcm2, the performance of the motor may be degraded at the main operation speed and the maximum speed.

The reciprocating compressor according to one or more embodiments of the disclosure with the outer rotor having such a moment of inertia may have a lower minimum speed and a lower speed fluctuation rate at the minimum speed than the reciprocating compressor according to the prior art, and thus may improve the fixed-temperature performance.

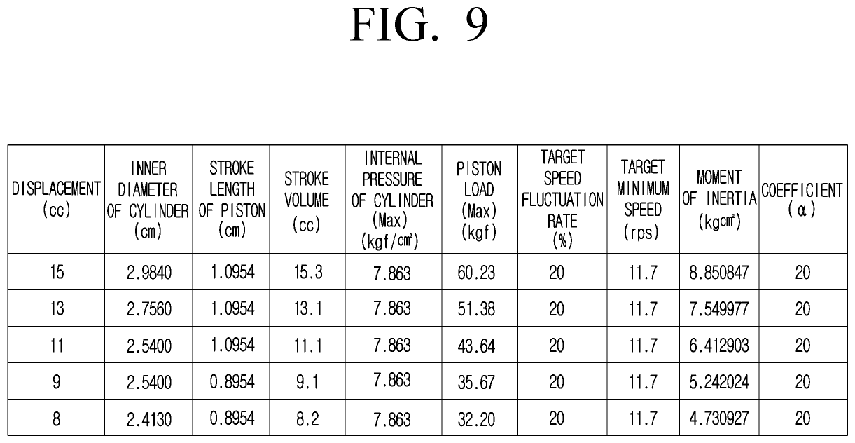

FIG. 9 is a table showing a target minimum speed, a target speed fluctuation rate, a moment of inertia, and a coefficient according to displacement of a reciprocating compressor using an inner rotor type motor according to one or more embodiments of the disclosure.

In FIG. 9, the target minimum speed represents the rotation speed of the rotor, and the moment of inertia refers to the moment of inertia of the rotor. The displacement is the displacement of the reciprocating compressor, and represents the stroke volume of the cylinder. The target speed fluctuation rate was experimentally confirmed using an ultra-high-speed camera.

In the case of calculating the moment of inertia of the rotor of a reciprocating compressor with a displacement of 15, by substituting the internal pressure of cylinder, the cross-sectional area of piston, the stroke length of piston, the target minimum speed, and the coefficient of the displacement of 15 in FIG. 9 into the above equation (2), 8.850847 may be obtained as the moment of inertia of the rotor. When measuring the rotor of this reciprocating compressor with an ultra-high-speed camera and calculating the speed fluctuation rate, the actual speed fluctuation rate may become 20% or less. Therefore, the target speed fluctuation rate of FIG. 9 may be satisfied.

In the case of calculating the moment of inertia of the rotor of a reciprocating compressor with a displacement of 13, by substituting the internal pressure of cylinder, the cross-sectional area of piston, the stroke length of piston, the target minimum speed, and the coefficient of the displacement of 13 in FIG. 9 into the above equation (2), 7.549977 may be obtained as the moment of inertia of the rotor. When the rotor of this reciprocating compressor is measured with an ultra-high-speed camera and the speed fluctuation rate is calculated, the actual speed fluctuation rate may become 20% or less. Therefore, the target speed fluctuation rate of FIG. 9 may be satisfied.

In the case of a displacement of 11, using equation (2) in the same way as the displacements of 15 and 13 described above, 6.412903 may be obtained as the moment of inertia of the rotor.

In the case of a displacement of 9, using equation (2) in the same way as the displacements of 15 and 13 described above, 5.242024 may be obtained as the moment of inertia of the rotor.

In the case of a displacement of 8, using equation (2) in the same way as the displacements of 15 and 13 described above, 4.730927 may be obtained as the moment of inertia of the rotor.

In the case of displacements of 11, 9, and 8, when the rotor of this reciprocating compressor is measured with an ultra-high-speed camera and the speed fluctuation rate thereof is calculated, the actual speed fluctuation rate may become 20% or less. Therefore, the target speed fluctuation rate of FIG. 9 may be satisfied.

Therefore, from FIG. 9, it can be seen that when the moment of inertia of the rotor is set to 4.7 kgcm2 to 8.9 kgcm2, the minimum speed of the rotor may be set to 11.7 rps, i.e., 700 rpm, and the speed fluctuation rate at the minimum speed may be set to 20% or less.

When the moment of inertia of the rotor is less than 4.7 kgcm2, the speed fluctuation rate at the minimum speed may exceed 20%. In addition, when the moment of inertia of the rotor exceeds 8.9 kgcm2, the performance of the motor may be degraded at the main operation speed and the maximum speed.

The reciprocating compressor according to one or more embodiments of the disclosure with the inner rotor having such a moment of inertia may have a lower minimum speed and a lower speed fluctuation rate at the minimum speed than the reciprocating compressor according to the prior art, and thus may improve the fixed-temperature performance thereof.

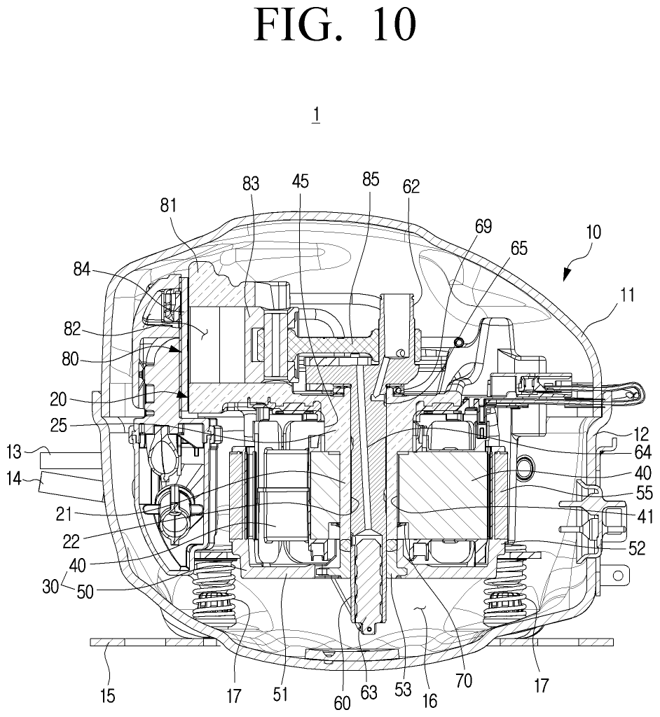

FIG. 10 is a cross-sectional view illustrating a reciprocating compressor according to one or more embodiments of the disclosure. For reference, FIG. 10 illustrates a reciprocating compressor using an outer rotor type motor in which a rotor is disposed on the outside of a stator.

Referring to FIG. 10, a reciprocating compressor 1 according to one or more embodiments of the disclosure may include a casing 10, a bearing block 20, a motor 30, and a compression part 80.

The casing 10 may form the exterior of the reciprocating compressor 1 and may be configured as a sealed container. The bearing block 20, the motor 30, and the compression part 80 may be disposed inside the casing 10. The casing 10 may include a lower casing 12 and an upper casing 11 covering the upper side of the lower casing 12.

The casing 10 may be formed by connecting the upper casing 11 and the lower casing 12, and may seal the interior of the casing 10 except for a refrigerant inlet pipe 13 and a refrigerant discharge pipe 14. In other words, the refrigerant may be introduced into the casing 10 through the refrigerant inlet pipe 13, and may be discharged to the outside of the casing 10 through the refrigerant discharge pipe 14.

An oil reservoir 16 for receiving oil may be provided at the lower portion of the lower casing 12.

Abase 15 for supporting the casing 10 may be provided at the bottom of the casing 10. The reciprocating compressor 1 may be disposed vertically with respect to the support surface by the base 15.

The bearing block 20 may be disposed inside the casing 10. The motor 30 may be disposed at the lower side of the bearing block 20, and the compression part 80 may be disposed at the upper side of the bearing block 20.

The bearing block 20 may be disposed in the lower casing 12. The bearing block 20 may be supported by a pair of elastic support members 17 disposed at the lower surface of the lower casing 12.

The bearing block 20 may include a fixed shaft 21. The fixed shaft 21 may be formed to extend vertically downward from the lower surface of the bearing block 20. The fixed shaft 21 may be formed in a cylindrical shape.

A shaft hole 22 may be formed inside the fixed shaft 21. The shaft hole 22 may be formed to have a circular cross-section. The shaft hole 22 may be formed to penetrate the fixed shaft 21 and the bearing block 20 upward and downward.

The outer circumferential surface of the fixed shaft 21 and the shaft hole 22 may be formed to be concentric.

A stator 40 may be disposed on the outer circumferential surface of the fixed shaft 21, and a rotation shaft 60 may be inserted into the shaft hole 22 of the fixed shaft 21.

The inner circumferential surface of the shaft hole 22 may be surface-processed to function as a bearing that supports the rotation of the rotation shaft 60. Therefore, the rotation shaft 60 may rotate with respect to the fixed shaft 21 while being inserted into the shaft hole 22.

A step portion 25 may be provided between the fixed shaft 21 and the lower surface of the bearing block 20. The step portion 25 may be formed to prevent the stator 40 from rotating with respect to the fixed shaft 21.

The motor 30 may be disposed at the lower portion of the bearing block 20. The motor 30 may be configured to generate a rotational force that operates the compression part 80. The motor 30 may include the stator 40 and a rotor 50.

The stator 40 may be disposed at the lower surface of the bearing block 20. The stator 40 may include a stator core and a coil. The stator core may be formed by laminating pressed steel plates.

The stator 40 may include a coupling hole 41. The coupling hole 41 may be formed at the center of the stator 40.

The fixed shaft 21 may be inserted into the coupling hole 41. The diameter of the coupling hole 41 may be formed larger than the diameter of the fixed shaft 21.

A fixed groove 45 may be provided on one surface of the stator 40, that is, on the upper surface of the stator 40 facing the bearing block 20. The fixed groove 45 may be formed to correspond to the step portion 25 of the bearing block 20. Therefore, when the step portion 25 of the fixed shaft 21 is inserted into the fixed groove 45 of the stator 40, the stator 40 may not rotate with respect to the fixed shaft 21. The step portion 25 and the fixed groove 45 may be formed to include a D-cut portion.

The stator 40 may be fixed to the fixed shaft 21. The stator 40 may be fixed to the fixed shaft 21 by a holder. The holder 70 and 77 may be disposed on the outer circumferential surface of the fixed shaft 21.

In detail, when the step portion 25 of the bearing block 20 is inserted into the fixed groove 45 of the upper surface of the stator 40, and the holder 70 and 77 is disposed on the fixed shaft 21 so that the holder 70 and 77 comes into contact with the lower surface of the stator 40, the stator 40 may be fixed to the fixed shaft 21 of the bearing block 20. In other words, when the holder 70 and 77 is fixed to the fixed shaft 21, the stator 40 may be fixed to the bearing block 20. When the stator 40 is fixed to the fixed shaft 21 by the holder 70 and 77, the stator 40 may not move up and down with respect to the fixed shaft 21.

The rotor 50 may be disposed on the outside of the stator 40. In other words, the stator 40 may be disposed on the inside of the rotor 50. Therefore, the rotor 50 may rotate on the outside of the stator 40 with the stator 40 as the center.

The rotor 50 may be fixed to one end of the rotation shaft 60. Therefore, when the rotor 50 rotates, the rotation shaft 60 may rotate integrally with the rotor 50.

The rotor 50 may be formed in a circular container shape. In other words, the rotor 50 may be formed in a hollow cylindrical shape with one end closed and the other end open. The stator 40 may be accommodated inside the rotor 50. When the rotor 50 is disposed on the outside of the stator 40, the moment of inertia of the rotor 50 may be increased. For example, the rotor 50 may be configured to have the moment of inertia of 8.3 to 15.6 kgcm2 as described above. In the case of this embodiment, the rotor 50 may be configured to have the moment of inertia of 13.2 kgcm2.

The rotor 50 may include a circular plate 51, a skirt 52, and a fixed boss 53.

The skirt 52 may extend vertically from the edge of the circular plate 51. In other words, the skirt 52 may be formed in a hollow cylindrical shape. The skirt 52 may be formed integrally with the circular plate 51.

A plurality of permanent magnets 55 may be disposed on the skirt 52. The plurality of permanent magnets 55 may be arranged at a regular interval in the circumferential direction of the skirt 52. The skirt 52 may be formed to have a certain gap from the stator 40. The gap between the plurality of permanent magnets 55 disposed on the skirt 52 and the outer surface of the stator 40 may form an air gap.

The fixed boss 53 may be fixed to the center of the circular plate 51. For example, the fixed boss 53 may be formed by injection molding on the circular plate 51.

The fixed boss 53 may be formed to be press-fitted and fixed to the rotation shaft 60. For example, the fixed boss 53 may include a through hole 54. The through hole 54 may be formed to penetrate the upper and lower surfaces of the fixed boss 53. The diameter of the through hole 54 of the fixed boss 53 may be defined to be tight fitted with the rotation shaft 60. In other words, the fixed boss 53 may be press-fitted and fixed to the rotation shaft 60. Therefore, when the rotor 50 rotates, the rotation shaft 60 may rotate integrally with the rotor 50.

The rotation shaft 60 may be inserted into the shaft hole 22 of the fixed shaft 21 of the bearing block 20. The rotation shaft 60 may be supported so as to rotate by the shaft hole 22. Therefore, when the rotor 50 rotates, the rotation shaft 60 may rotate inside the shaft hole 22 of the fixed shaft 21.

A head part 61 may be provided on the upper end of the rotation shaft 60. The head part 61 may be formed to have a diameter larger than the diameter of the rotation shaft 60. The head part 61 may be formed to rotate integrally with the rotation shaft 60.

A bearing 69 supporting the head part 61 may be disposed between the head part 61 and the upper surface of the bearing block 20. Therefore, when the rotation shaft 60 rotates, the head part 61 may rotate with respect to the upper surface of the bearing block 20.

A crank shaft 62 may be provided on the upper surface of the head part 61. The crank shaft 62 may be formed perpendicular to the upper surface of the head part 61. The crank shaft 62 may be formed to be eccentric with the rotation shaft 60. In other words, the center line of the rotation shaft 60 may be spaced apart from the center line of the crank shaft 62 by a certain distance. The stroke length of the piston may be twice the eccentric distance between the crank shaft 62 and the rotation shaft 60. A connecting rod 85 may be connected to the crank shaft 62.

An oil pump 63 may be disposed at the lower portion of the rotation shaft 60. The lower portion of the rotation shaft 60 where the oil pump 63 is disposed may be integrally connected to the rotor 50. The lower end of the rotation shaft 60 may protrude below the rotor 50 and be immersed in the oil reservoir 16.

The rotation shaft 60 may include an oil supply passage. The oil supply passage may include a first oil passage 64 formed to penetrate the rotation shaft 60 upward to downward and a second oil passage 65 formed in a helical shape on the outer circumferential surface of the rotation shaft 60.

Therefore, when the rotation shaft 60 rotates, the oil in the oil reservoir 16 may be supplied upward by the oil pump 63. Some of the oil supplied by the oil pump 63 may be supplied to the upper side of the rotation shaft 60 through the first oil passage 64. In addition, the remaining oil may be supplied between the outer circumferential surface of the rotation shaft 60 and the inner surface of the shaft hole 22 through the second oil passage 65.

The compression part 80 may be configured to compress and discharge the refrigerant introduced through the refrigerant inlet pipe 13. The compression part 80 may be provided on the upper surface of the bearing block 20.

The compression part 80 may include a cylinder 81, a piston 83, and a connecting rod 85.

The cylinder 81 may be formed on the upper surface of the bearing block 20. A compression chamber 82 having a circular cross-section may be formed inside the cylinder 81. A cylinder head 84 having an inlet valve and a discharge valve may be disposed on the outer end of the cylinder 81.

The piston 83 may be inserted into the hollow of the cylinder 81. The piston 83 may be configured to reciprocate in a straight line a certain distance along the inner surface of the compression chamber 82 of the cylinder 81.

The piston 83 may be connected to one end of the connecting rod 85. The other end of the connecting rod 85 may be connected to the crank shaft 62 of the rotation shaft 60. Therefore, when the rotation shaft 60 rotates, the piston 83 may reciprocate linearly in the compression chamber 82 of the cylinder 81 by the crank shaft 62 and the connecting rod 85.

The cylinder 81 and the piston 83 may be configured to satisfy the relationship of the above-described equation (2) by considering the moment of inertia of the rotor 50.

When the piston 83 reciprocates linearly in the compression chamber 82 of the cylinder 81, the refrigerant may be introduced into the compression chamber 82 through the inlet valve, compressed, and then discharged outside the compression chamber 82 through the discharge valve.

The instantaneous speed of the rotor of the reciprocating compressor having the structure as illustrated in FIG. 10 was measured to calculate the speed fluctuation rate according to the operation speed.

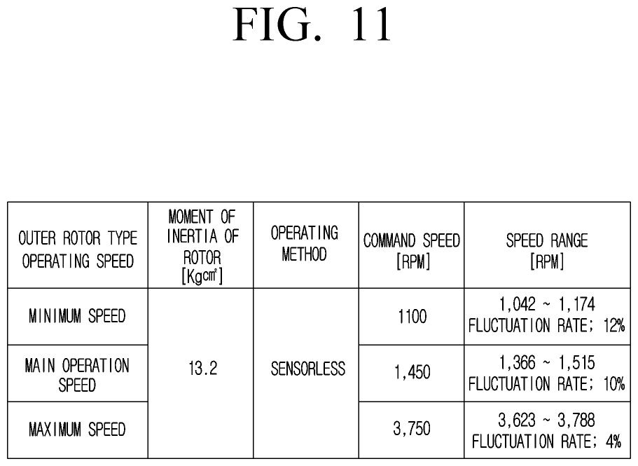

FIG. 11 is a table showing a speed fluctuation rate according to an operation speed of a reciprocating compressor using an outer rotor type motor according to one or more embodiments of the disclosure.

In FIG. 11, the moment of inertia of the rotor of the outer rotor type reciprocating compressor is 13.2 kgcm2, and the operating method is a sensorless method.

Referring to FIG. 11, when the reciprocating compressor rotates at the minimum speed of the commanded speed of 1,100 rpm, the range of the actual speed of the rotor is 1,042 rpm to 1,174 rpm, and the speed fluctuation rate is about 12%.

When the reciprocating compressor rotates at the main operation speed of the commanded speed of 1,450 rpm, the range of the actual speed of the rotor is 1,366 rpm to 1,515 rpm, and the speed fluctuation rate is about 10%.

When the reciprocating compressor rotates at the maximum speed of the commanded speed of 3,750 rpm, the range of the actual speed of the rotor is 3,623 rpm to 3,788 rpm, and the speed fluctuation rate is about 4%.

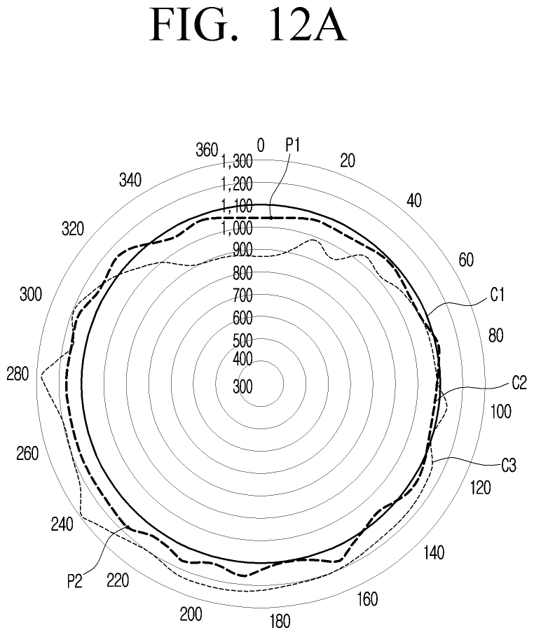

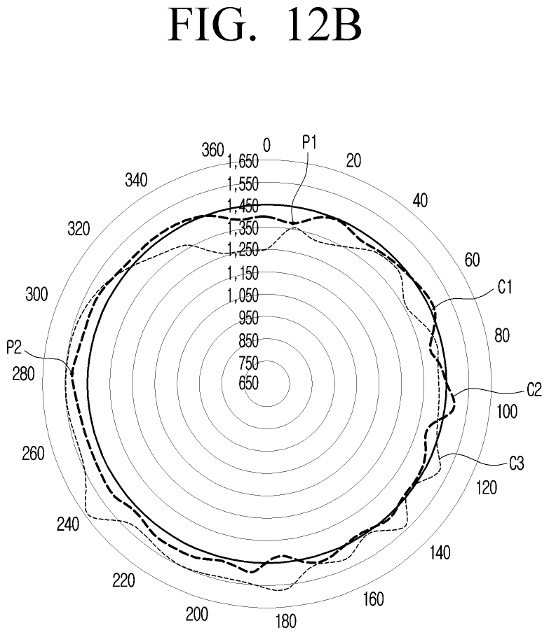

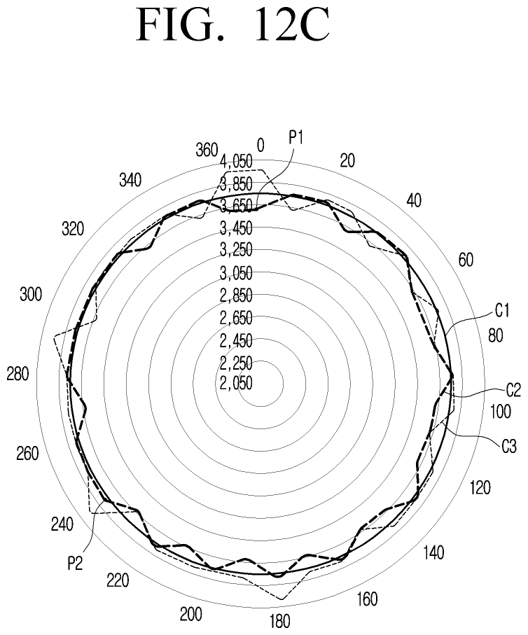

Such command speeds and actual speeds of the rotor are illustrated in FIGS. 12A, 12B, and 12C.

FIG. 12A is a graph illustrating a speed fluctuation rate when a reciprocating compressor using an outer rotor type motor according to one or more embodiments of the disclosure operates at a low speed. FIG. 12B is a graph illustrating a speed fluctuation rate when a reciprocating compressor using an outer rotor type motor according to one or more embodiments of the disclosure operates at a main operation speed. FIG. 12C is a graph illustrating a speed fluctuation rate when a reciprocating compressor using an outer rotor type motor according to one or more embodiments of the disclosure operates at a maximum speed.

In FIGS. 12A, 12B, and 12C, multiple concentric circles represent a rotation speed of the rotor, and the unit is rpm. The numbers on the outermost circle represent the rotational angle of the rotor, and the unit is degree. In addition, in FIGS. 12A, 12B, and 12C, the solid line C1 represents the command speed, and the thick dotted line C2 represents the actual speed of the rotor according to one or more embodiments of the disclosure. The thin dotted line C3 represents the actual speed of the rotor according to the prior art. The actual speed of the rotor is the instantaneous speed of the rotor measured using an ultra-high-speed camera.

Referring to FIG. 12A, the command speed, which is the minimum speed, is constant at 1,100 rpm while the rotor rotates once, that is, from 0 degrees to 360 degrees. However, the actual speed of the rotor varies from a maximum of 1,174 rpm to a minimum of 1,042 rpm. In detail, the instantaneous minimum speed is 1,042 rpm at about zero (0) degrees P1, and the instantaneous maximum speed is 1,174 rpm at about 220 degrees P2.

Therefore, in the case that the command speed is 1,100 rpm, the instantaneous maximum speed is 1,174 rpm, and the instantaneous minimum speed is 1,042 rpm, when calculated using the above-described equation (1), the speed fluctuation rate is 12%. Accordingly, when the command speed is 1,100 rpm, the speed fluctuation rate of the rotor may be said to be approximately 12%.

Referring to FIG. 12B, the command speed, which is the main operation speed, is constant at 1,450 rpm while the rotor rotates once, that is, from 0 degrees to 360 degrees. However, the actual speed of the rotor varies from a maximum of 1,515 rpm to a minimum of 1,366 rpm. In detail, the instantaneous minimum speed is 1,366 rpm at about 10 degrees P1, and the instantaneous maximum speed is 1,515 rpm at about 280 degrees P2.

Therefore, in the case that the command speed is 1,450 rpm, the instantaneous maximum speed is 1,515 rpm, and the instantaneous minimum speed is 1,366 rpm, when calculated using the equation (1), the speed fluctuation rate is 10.3%. Accordingly, when the command speed is 1,450 rpm, the speed fluctuation rate of the rotor may be said to be approximately 10%.

Referring to FIG. 12C, the command speed, which is the maximum speed, is constant at 3,750 rpm while the rotor rotates once, that is, from 0 degrees to 360 degrees. However, the actual speed of the rotor varies from a maximum of 3,788 rpm to a minimum of 3,623 rpm. In detail, the instantaneous minimum speed is 3,623 rpm at about zero (0) degrees P1, and the instantaneous maximum speed is 3,788 rpm at about 240 degrees P2.

Therefore, in the case that the command speed is 3,750 rpm, the instantaneous maximum speed is 3,788 rpm, and the instantaneous minimum speed is 3,623 rpm, when calculated using the equation (1), the speed fluctuation rate is 4.4%. Accordingly, when the command speed is 3,750 rpm, the speed fluctuation rate of the rotor may be said to be approximately 4%.

In addition, when the command speed is 500 rpm, the speed fluctuation rate is about 18%. Therefore, the reciprocating compressor using the outer rotor type motor according to one or more embodiments of the disclosure may have the minimum speed set to 500 rpm and the speed fluctuation rate at the minimum speed set to 20% or less. Accordingly, when the reciprocating compressor according to one or more embodiments of the disclosure is used in a refrigerator, the fixed-temperature performance of the refrigerator may be improved.

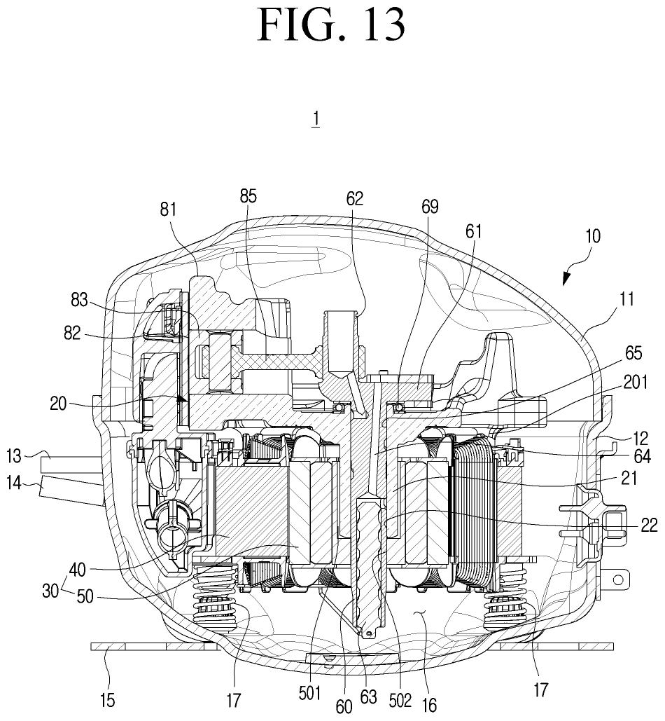

FIG. 13 is a cross-sectional view illustrating a reciprocating compressor according to one or more embodiments of the disclosure. For reference, FIG. 13 illustrates a reciprocating compressor using an inner rotor type motor in which a rotor is disposed on the inside of a stator.

Referring to FIG. 13, a reciprocating compressor 1 according to one or more embodiments of the disclosure may include a casing 10, a bearing block 20, a motor 30, and a compression part 80.

The casing 10 may be form the exterior of the reciprocating compressor 1 and may be configured as a sealed container. The bearing block 20, the motor 30, and the compression part 80 may be disposed inside the casing 10. The casing 10 may include a lower casing 12 and an upper casing 11 covering the upper side of the lower casing 12.

The casing 10 may be formed by connecting the upper casing 11 and the lower casing 12, and may seal the interior of the casing 10 except for a refrigerant inlet pipe 13 and a refrigerant discharge pipe 14. In other words, the refrigerant may be introduced into the casing 10 through the refrigerant inlet pipe 13, and may be discharged to the outside of the casing 10 through the refrigerant discharge pipe 14.

An oil reservoir 16 for receiving oil may be provided at the lower portion of the lower casing 12.

Abase 15 for supporting the casing 10 may be provided at the bottom of the casing 10. The reciprocating compressor 1 may be disposed vertically with respect to the support surface by the base 15.

The bearing block 20 may be disposed inside the casing 10. The motor 30 may be disposed at the lower side of the bearing block 20, and the compression part 80 may be disposed at the upper side of the bearing block 20.

The bearing block 20 may be disposed in the lower casing 12. The bearing block 20 may be supported by a pair of elastic support members 17 disposed at the lower surface of the lower casing 12.

The bearing block 20 may include a fixed shaft 21. The fixed shaft 21 may be formed to extend vertically downward from the lower surface of the bearing block 20. The fixed shaft 21 may be formed in a cylindrical shape.

A shaft hole 22 may be formed inside the fixed shaft 21. The shaft hole 22 may be formed with a circular cross-section. The shaft hole 22 may be formed to penetrate the fixed shaft 21 and the bearing block 20 upward and downward.

The fixed shaft 21 may be inserted into a receiving groove 501 of the rotor 50. A rotation shaft 60 may be inserted into the shaft hole 22 of the fixed shaft 21.

The inner circumferential surface of the shaft hole 22 may be surface-processed to function as a bearing that supports the rotation of the rotation shaft 60. Therefore, the rotation shaft 60 may rotate with respect to the fixed shaft 21 while being inserted into the shaft hole 22.

The bearing block 20 may include a plurality of fixed protrusions 201 extending downward from the lower surface thereof. The plurality of fixed protrusions 201 may be formed around the fixed shaft 21. The plurality of fixed protrusions 201 may be formed at regular intervals in the circumferential direction centered on the fixed shaft 21. A bolt hole into which a bolt is fastened may be formed on the lower surface of each of the plurality of fixed protrusions 201. The plurality of fixed protrusions 201 may be formed to fix the stator 40.

In this embodiment, four fixed protrusions 201 may be provided on the lower surface of the bearing block 20, and bolt holes may be formed on the lower surfaces of the four fixed protrusions 201.

The motor 30 may be disposed on the lower side of the bearing block 20. The motor 30 may be configured to generate a rotational force that operates the compression part 80. The motor 30 may include the stator 40 and the rotor 50.

The stator 40 may be disposed at the lower surface of the bearing block 20. The stator 40 may be include a stator core and a coil. The stator core may be formed by laminating pressed steel plates.

The stator 40 may include a rotor hole and a plurality of coupling holes. The rotor hole may be formed at the center of the stator 40, and the plurality of coupling holes may be formed at the edge of the stator 40. The rotor hole may be formed so that the rotor 50 is inserted into and rotated inside the rotor hole. The plurality of coupling holes may be formed to correspond to the bolt holes of the plurality of fixed protrusions 201 of the bearing block 20.

The stator 40 may be fixed to the plurality of fixing protrusions 201 of the bearing block 20. The stator 40 may be fixed to the bearing block 20 by inserting a plurality of bolts into the plurality of coupling holes of the stator 40 and fastening the plurality of bolts to the plurality of bolt holes of the bearing block 20.

The rotor 50 may be disposed at the center of the stator 40. In other words, the stator 40 may be disposed on the outside of the rotor 50. Therefore, the rotor 50 may rotate on the inside of the stator 40 around the fixed shaft 21.

The rotor 50 may be formed in a hollow cylindrical shape. The rotor 50 may include a rotor core and a plurality of permanent magnets. The rotor core may be formed by laminating press-processed steel plates. The rotor 50 may be formed to have an appropriate moment of inertia. For example, the rotor 50 may be formed to have the moment of inertia of 4.7 to 8.9 kgcm2 as described above.

The rotor 50 may include the receiving groove 501 and a fixing hole 502. The fixing hole 502 may be formed at the bottom of the receiving groove 501. Therefore, the receiving groove 501 and the fixing hole 502 may form a step. The diameter of the receiving groove 501 may be formed larger than the diameter of the fixing hole 502. The depth of the receiving groove 501 may be longer than the axial length of the fixing hole 502.

The fixed shaft 21 of the bearing block 20 may be inserted into the receiving groove 501 of the rotor 50. The diameter of the receiving groove 501 may be formed larger than the diameter of the fixed shaft 21. Therefore, when the rotor 50 rotates, the rotor 50 may not interfere with the fixed shaft 21 of the bearing block 20.

The rotation shaft 60 may be inserted and fixed into the fixing hole 502. The fixing hole 502 of the rotor 50 may be fixed to the lower portion of the rotation shaft 60. Therefore, when the rotor 50 rotates, the rotation shaft 60 may rotate integrally with the rotor 50.

The rotation shaft 60 may be inserted into the shaft hole 22 of the fixed shaft 21 of the bearing block 20. The rotation shaft 60 may be supported so as to be rotatable by the shaft hole 22. Therefore, when the rotor 50 rotates, the rotation shaft 60 may rotate inside the shaft hole 22 of the fixed shaft 21.

A head part 61 may be provided on the upper end of the rotation shaft 60. The head part 61 may be formed to have a diameter larger than the diameter of the rotation shaft 60. The head part 61 may be formed to rotate integrally with the rotation shaft 60.

A bearing 69 supporting the head part 61 may be disposed between the head part 61 and the upper surface of the bearing block 20. Therefore, when the rotation shaft 60 rotates, the head part 61 may rotate with respect to the upper surface of the bearing block 20.

A crank shaft 62 may be provided on the upper surface of the head part 61. The crank shaft 62 may be formed perpendicular to the upper surface of the head part 61. The crank shaft 62 may be formed to be eccentric with the rotation shaft 60. In other words, the center line of the rotation shaft 60 may be spaced apart from the center line of the crank shaft 62 by a certain distance. The stroke length of the piston may be twice the eccentric distance between the crank shaft 62 and the rotation shaft 60. A connecting rod 85 may be connected to the crank shaft 62.

An oil pump 63 may be disposed at the lower portion of the rotation shaft 60. The lower portion of the rotation shaft 60 where the oil pump 63 is disposed may be integrally connected to the rotor 50. The lower end of the rotation shaft 60 may protrude below the rotor 50 and be immersed in the oil reservoir 16.

The rotation shaft 60 may include an oil supply passage. The oil supply passage may include a first oil passage 64 formed to penetrate the rotation shaft 60 upwardly and downwardly and a second oil passage 65 formed in a helical shape on the outer circumferential surface of the rotation shaft 60.

Therefore, when the rotation shaft 60 rotates, the oil in the oil reservoir 16 may be supplied upwardly by the oil pump 63. Some of the oil supplied by the oil pump 63 may be supplied to the upper side of the rotation shaft 60 through the first oil passage 64. In addition, the remaining oil may be supplied between the outer circumferential surface of the rotation shaft 60 and the inner circumferential surface of the shaft hole 22 through the second oil passage 65.

The compression part 80 may be configured to compress and discharge the refrigerant introduced through the refrigerant inlet pipe 13. The compression part 80 may be provided on the upper surface of the bearing block 20.

The compression part 80 may include a cylinder 81, a piston 83, and a connecting rod 85.

The cylinder 81 may be formed on the upper surface of the bearing block 20. A compression chamber 82 having a circular cross-section may be formed inside the cylinder 81. A cylinder head 84 having an inlet valve and a discharge valve may be disposed on the outer end of the cylinder 81.

The piston 83 may be inserted into the hollow of the cylinder 81. The piston 83 may be configured to reciprocate in a straight line a certain distance along the inner surface of the compression chamber 82 of the cylinder 81.

The piston 83 may be connected to one end of the connecting rod 85. The other end of the connecting rod 85 may be connected to the crank shaft 62 of the rotation shaft 60. Therefore, when the rotation shaft 60 rotates, the piston 83 may reciprocate linearly in the compression chamber 82 of the cylinder 81 by the crank shaft 62 and the connecting rod 85.

The cylinder 81 and the piston 83 may be configured to satisfy the relationship of the above-described equation (2) by considering the moment of inertia of the rotor 50.

When the piston 83 reciprocates linearly in the compression chamber 82 of the cylinder 81, the refrigerant may be introduced into the compression chamber 82 through the inlet valve, compressed, and then discharged outside the compression chamber 82 through the discharge valve.

For the reciprocating compressor using the inner rotor type motor having the structure as illustrated in FIG. 13, the instantaneous speed of the rotor at low speed was measured and the speed fluctuation rate was calculated.

For example, when the reciprocating compressor was operated at 1,100 rpm, the speed fluctuation rate is about 15%. In addition, when the reciprocating compressor was operated at 700 rpm, the speed fluctuation rate is about 19%. Therefore, the reciprocating compressor using an inner rotor type motor according to one or more embodiments of the disclosure may have a minimum speed of 700 rpm and a speed fluctuation rate at the minimum speed of 20% or less. Accordingly, when the reciprocating compressor according to one or more embodiments of the disclosure is used in a refrigerator, the fixed-temperature performance of the refrigerator may be improved.

In the foregoing, the disclosure has been shown and described with reference to various embodiments. However, it is understood by those skilled in the art that various changes may be made in form and detail without departing from the scope of the disclosure as defined by the appended claims and equivalents thereof.

1. A reciprocating compressor comprising:
a cylinder;
a piston to be disposed inside the cylinder and to reciprocate a certain distance while inside the cylinder;
a connecting rod to be connected to the piston;
a rotation shaft configured to operate the connecting rod;
a rotor configured to rotate integrally with the rotation shaft; and
a stator to be disposed on an inside of the rotor along a direction toward the rotation shaft or an outside of the rotor along the direction toward the rotation shaft,
wherein a speed fluctuation rate of the rotor is 20% or less, a moment of inertia of the rotor, an internal pressure of the cylinder, a cross-sectional area and a stroke length of the piston, and a minimum speed of the rotor having a relationship as follows:
$$moment of inertia of rotor \geq \frac{\begin{matrix}internal pressure of cylinder \times cross - \\ sectional area of pistion \times stroke length of pistion\end{matrix}}{minimum {speed}^{2}} \times α$$
wherein a unit of the moment of inertia of the rotor is kgcm², a unit of the internal pressure of the cylinder is kgf/cm², a unit of cross-sectional area of the piston is cm², a unit of the stroke length of the piston is cm, a unit of the minimum speed is round/second (rps), and α is a coefficient of a moment of inertia of the reciprocating compressor.

2. The reciprocating compressor of claim 1, wherein
based on the stator being disposed on the outside of the rotor, the moment of inertia of the rotor is 4.7 to 8.9 kgcm².

3. The reciprocating compressor of claim 1, wherein
based on the stator being disposed on the inside of the rotor, the moment of inertia of the rotor is 8.3 to 15.6 kgcm².

4. The reciprocating compressor of claim 1, wherein
based on the stator being disposed on the outside of the rotor, the minimum speed of the rotor is 11.7 rps.

5. The reciprocating compressor of claim 1, wherein
based on the stator being disposed on the inside of the rotor, the minimum speed of the rotor is 8.3 rps.

6. The reciprocating compressor of claim 1, wherein
based on the stator being disposed on the outside of the rotor, the coefficient of the moment of inertia is 20.

7. The reciprocating compressor of claim 1, wherein
based on the stator being disposed on the inside of the rotor, the coefficient of the moment of inertia is 18.

8. The reciprocating compressor of claim 1, wherein
the speed fluctuation rate of the rotor has a relationship as follows:
$$speed fluctuation rate = \frac{instaneous maximum speed - instaneous minimum speed}{command speed} \times 100 \% .$$

9. The reciprocating compressor of claim 1, wherein
the internal pressure of the cylinder is 7.863 kgf/cm².

10. The reciprocating compressor of claim 1, wherein
the cylinder, the piston, and the connecting rod are provided on an upper side of a bearing block, and the stator and the rotor are provided on a lower side of the bearing block.
